(19) United States
(12) Patent Application Publication
(10) Pub. No.: US 2009/0302466 A1
(43) Pub. Date: Dec. 10, 2009

(54) SEMICONDUCTOR DEVICE AND METHOD FOR MANUFACTURING THE SAME

(75) Inventors: Masanobu SHOJI, Tsuruoka-shi (JP); Toru FUJITA, Tsuruoka-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/470,020

(22) Filed: May 21, 2009

(30) Foreign Application Priority Data
Jun. 10, 2008 (JP) 2008-151398

(51) Int. Cl. H01L 23/498; H01L 21/56

(52) U.S. Cl. 257/737; 438/124; 257/E23.068; 257/E21.502

(57) ABSTRACT

A semiconductor device includes a first metal post that has a first face, a second metal post that has a second face, a first plated layer that is provided on the first face, the first plated layer being discontiguous with an outer edge of the first face, a second plated layer that is provided on the second face, the second plated layer being discontiguous with an outer edge of the second face, an integrated circuit element that is fixed on the first face; a conductor that electrically connects the integrated circuit element with the second metal post, and a resin that seals the integrated circuit element and the conductor.

The entire disclosure of Japanese Patent Application No. 2008-151398, filed Jun. 10, 2008 is expressly incorporated by reference herein.

### BACKGROUND

1. Technical Field

The present invention relates to a substrate, a method for manufacturing the substrate, a semiconductor device and a method for manufacturing the semiconductor device.

2. Related Art

JP-A-2001-217353 is an example of related art. The second embodiment described in the example (see descriptions in the paragraph number [0075] to [0080] and FIGS. 8 through 12) discloses that a conductive film is deposited on a conductive foil, and the conductive foil is subsequently etched by using the conductive film as a mask so as to form “eaves” which is made of the conductive film and to form a separation trench that separates the conductive foil.

According to the example, the “eaves” that is adhesively bonded with a conducting path is buried in an insulating resin thereby a so-called anchor effect occurs with which it is possible to prevent the conducting path from falling out from the insulating resin. Moreover, when the conductive foil is etched by wet-etching using the conductive film as a mask, the conductive foil is isotropically etched so that the above-mentioned “eaves” is automatically formed and it is not necessary to have a step of forming the “eaves” separately. However, providing the “eaves” has the following disadvantages A) to C).

A) Referring to FIG. 16A, an eaves 101a for example protrudes out in a crosswise direction when viewed in section, there is no support right under the eaves and its rigidity is lower than that of a conductive film 101 that is provided on a conductive foil 102. Therefore there is a possibility that the eaves 101a can be broken by a shock caused by for example wire-bonding (more specifically at the time when one end of a gold wire is jointed onto the conductive film 101). For instance, the eaves 101a is broken as shown in FIG. 16B, and if the broken part of the eaves 101a falls into a separation trench 103 and then is sealed with an insulating resin 104, conducting paths 102a, 102b can be short-circuited through the eaves 101a (in other words, a migration failure occurs). The migration failure can lower an yield ratio of the semiconductor device and reduce reliability of the device.

B) Referring to FIG. 16A, the eaves 101a protrudes out in the crosswise direction when viewed in section, thereby a burr is often formed at the tip of the eaves. The burr can be easily broken and its shape is unstable (in other words, the shape never be constant). For this reason, at a time of for example wire-bonding, a jointing area in the conductive film 101 sometimes cannot be properly recognized and it could lead to a lower productivity in the wire-bonding process.

C) Referring to FIG. 16A, the eaves 101a is formed over the separation trench 103 and the eaves 101a becomes an obstacle when the separation trench 103 is filled with the insulating resin 104. Thereby there is a possibility that the insulating resin 104 cannot be supplied sufficiently enough and it reduces reliability of a resin package.

### SUMMARY

An advantage of some aspects of the present invention is to provide a substrate and a manufacturing method thereof with which it is possible to improve a yield ratio and reliability of a semiconductor device, and to provide a semiconductor device and a method for manufacturing the semiconductor device.

1) Substrate

A substrate for fixing an element according to a first aspect of the invention includes a metal post that is provided in a plural number and a plated layer, the metal post having a first face and a second face that face opposite sides, and the plated layer being provided on the first face of each metal post such that the plated layer is disposed discontiguous with an outer edge of the first face,

According to the first aspect of the invention, eaves that is made of the plated layer does not exist (or is not formed in a manufacturing process). Consequently the rigidity of the plated layer as a whole can be increased and it is possible to prevent tips of the plated layer from being broken or come off. In addition, chances of burr formation are reduced, which contributes to the stabilization of a shape in plan (hereunder referred as a planar shape) of the metal post.

For example, when a semiconductor device is manufactured by using the substrate according to the first aspect of the invention, tips of the plated layer is prevented from being broken or come off. Therefore it is possible to prevent short-circuit between metal posts caused by the plated layer (in other words, a migration failure). Moreover, chances of burr formation are reduced so that a jointing region of the metal post can be accurately recognized, which increases the yield ratio of the semiconductor device. Furthermore, in a resin sealing step in which an IC element and a conductor are sealed with resin, “eaves” which can be an obstacle in the sealing step does not exist so that the resin can easily fill among the metal posts. In this way it is possible to increases the reliability of the resin package.

In this case, the plurality of the metal posts may be arranged in more than one line both in a longitudinal direction and a crosswise direction when viewed in plan.

In this way, the metal posts can be used as a die pad or an external terminal on which various elements having a wide variety of functions and shapes such as an IC element having an IC circuit, a passive element including a resistor, a capacitor and an inductor, and the like can be mounted. More specifically the metal posts can be used as the die pad or the external terminal depending on a shape and size of an IC fixing area. Thereby it is not necessary to prepare a specific die pad, lead frame and substrate (interposer or the like) which are especially made depending on a type of the IC element in order to assemble the semiconductor device. This means that a single type of the substrate for mounting an element and an external terminal can be adopted for various types of elements without limiting layouts (arrangements) of the pad terminal. In this way, it is possible to reduce the manufacturing cost of the substrate and the semiconductor device that is equipped with the substrate.

In this case, the metal posts may have the same shape and the same size. In this way, only one type of the shape and the size of the metal posts when viewed in plan is provided in the substrate so that it is possible to increase the versatility of the substrate for various elements.

In this case, the substrate may further include a connecting part coupling the metal posts at a some point from the first face to the second face.

In this case, the substrate may further include a supporting substrate that supports the second face of the metal post, the metal post may be provided in a plural number, and the plurality of the metal posts may be bonded to the supporting substrate with adhesive.

In this case, the plurality of the metal posts may include a first metal post and a second metal post, the second metal post may be smaller than the first metal post when viewed in plan, and the second metal post may be disposed around the first metal post.

In this way, the first metal post can be used as a die pad and the second metal post can be used as an external terminal. Consequently the substrate can be used as for example a lead frame for a quad flat non-leaded package (QFN).

2) Method for Manufacturing Substrate

A method for manufacturing a substrate on which an element is fixed according to a second aspect of the invention includes forming a metal post that has a first face and a second face, the first face and the second face facing opposite sides, and the metal post being provided in a plural number, and providing a plated layer on the first face of the metal post such that the plated layer is disposed discontiguous with an outer edge of the first face.

According to the second aspect of the invention, it is possible to prevent the “eaves” that is made of the plated layer from being formed so that the rigidity of the plated layer as a whole can be increased and tips of the plated layer will not be broken or come off. In addition, chances of burr formation are reduced, which contributes to the stabilization of the planar shapes of the metal post.

For example, when a semiconductor device is manufactured by using the substrate, tips of the plated layer is prevented from being broken or come off. Therefore it is possible to prevent the migration failure from occurring. Moreover, chances of burr formation are reduced so that a jointing region of the metal post can be accurately recognized, which increases the yield ratio of the semiconductor device. Furthermore, in a resin sealing step, “eaves” which can be an obstacle in the sealing step does not exist so that the resin can easily fill among the metal posts In this way it is possible to increases the reliability of the resin package.

3) Semiconductor Device

A semiconductor device according to a third aspect of the invention includes a substrate including a metal post that is provided in a plural number and a plated layer, the metal post having a first face and a second face that face opposite sides, the plated layer being provided on the first face of the metal post such that the plated layer is disposed discontiguous with an outer edge of the first face, and the plurality of the metal posts including a first metal post and a second metal post, an integrated circuit (IC) element fixed on the first face of the first metal post, a conductor coupling the IC element and the second metal post electrically, and a resin sealing the IC element and the conductor.

A semiconductor device according to a fourth aspect of the invention includes a first metal post having a first face, a second metal post having a second face, a first plated layer provided on the first face and being discontiguous with an outer edge of the first face, a second plated layer provided on the second face and being discontiguous with an outer edge of the second face, an integrated circuit element fixed on the first face, a conductor electrically connecting the integrated circuit element and the second metal post, and a resin sealing the integrated circuit element and the conductor.

According to the third and forth aspects of the invention, the “eaves” does not exist so that the rigidity of the plated layer as a whole can be increased and tips of the plated layer will not be broken or come off. Therefore it is possible to prevent the migration failure due to the brake or peel off of the plated layer from occurring. In addition, chances of burr formation are reduced, which contributes to the stabilization of the planar shapes of the metal post. In this way, in a wire-bonding process, for example, a jointing area in the metal post can be precisely recognized and it is possible to increase the manufacturing efficiency of the semiconductor device. Moreover, in the resin sealing step, the “eaves” which can be an obstacle in the sealing step does not exist so that the resin can easily fill among the metal posts. Thereby it is possible to prevent a void space and the like from being generated in the resin package, which increases the reliability of the resin package.

In this case, the first metal post may have a shape and a size that are same as a shape and a size of the second metal post.

In this case, the second plated layer may be smaller than the first plated layer.

4) Method for Manufacturing Semiconductor Device

A method for manufacturing a semiconductor device according to a fifth aspect of the invention includes providing a substrate that includes a metal post which is provided in a plural number and a plated layer, the metal post having a first face and a second face that face opposite sides, the plated layer being provided on the first face of the metal post such that the plated layer is disposed discontiguous with an outer edge of the first face, and the plurality of the metal posts including a first metal post and a second metal post, placing an integrated circuit (IC) element on the first face of the first metal post, coupling the IC element and the second metal post electrically with a conductor, and sealing the IC element and the conductor with a resin.

A method for manufacturing a semiconductor device according to a sixth aspect of the invention includes providing a substrate that includes a first metal post that has a first face, a second metal post that has a second face, a first plated layer that is provided on the first face and is discontiguous with an outer edge of the first face, and a second plated layer that is provided on the second face and is discontiguous with an outer edge of the second face, placing an integrated circuit element on the first face, connecting the integrated circuit element and the second metal post electrically with a conductor, and sealing the integrated circuit element and the conductor with a resin.

According to the fifth and sixth aspect of the invention, it is possible to prevent the “eaves” that is made of the plated layer from being formed so that the rigidity of the plated layer as a whole can be increased and tips of the plated layer will not be broken or come off. Therefore it is possible to prevent the migration failure due to the brake or peel off of the plated layer from occurring. In addition, chances of burr formation are reduced, which contributes to the stabilization of the planar shapes of the metal post. In this way, in a wire-bonding process, for example, a jointing area in the metal post can be precisely recognized and it is possible to increase the manufacturing efficiency of the semiconductor device. Moreover, in the resin sealing step, the “eaves” which can be an obstacle in the sealing step does not exist so that the resin can easily fill among the metal posts. Thereby it is possible to prevent a void space and the like from being generated in the resin package, which increases the reliability of the resin package.

### BRIEF DESCRIPTION OF THE DRAWINGS

The invention will be described with reference to the accompanying drawings, wherein like numbers reference like elements.

FIGS. 1A to 1F show a method for manufacturing a substrate 50 according to a first embodiment of the invention.

FIGS. 2A to 2F show another method for manufacturing the substrate 50 according to the first embodiment.

FIGS. 3A and 3B illustrate a configuration example of the substrate 50 according to the first embodiment.

FIGS. 4A to 4E show a method for manufacturing a semiconductor device 100 according to the first embodiment.

FIGS. 5A to 5F show a method for manufacturing a substrate 60 according to a second embodiment of the invention.

FIGS. 6A to 6F show another method for manufacturing the substrate 60 according to the second embodiment.

FIG. 7 illustrates a configuration example of the substrate 60 according to the second embodiment.

FIGS. 8A and 8B show the configuration example of the substrate 60 according to the second embodiment.

FIGS. 9A and 9E show a method for manufacturing a semiconductor device 200 according to the second embodiment.

FIGS. 10A to 10F show a method for manufacturing a substrate 70 according to a third embodiment of the invention.

FIGS. 11A to 11c show the method for manufacturing the substrate 70 according to the third embodiment.

FIGS. 12A to 12C show the method for manufacturing the substrate 70 according to the third embodiment.

FIG. 13 illustrates a configuration example of the substrate 70 according to the third embodiment.

FIGS. 14A to 14D show a method for manufacturing a semiconductor device 300 according to the third embodiment.

FIGS. 15A and 15B illustrate one of advantageous effects in the first through third embodiments.

FIGS. 16A and 16B illustrate disadvantages of a related art.

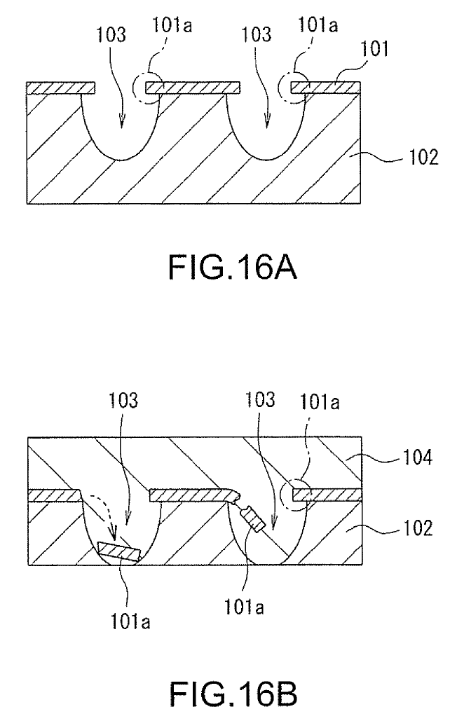

### DESCRIPTION OF EXEMPLARY EMBODIMENTS

Embodiments of the invention will be described. In the following description, the identical numerals are given to the identical structures and those explanations will not be repeatedly given.

### First Embodiment

In a first embodiment, a method for manufacturing a substrate 50 which can for example serve as a lead frame for a quad flat non-leaded package (QFN) will be described followed by a method for manufacturing a semiconductor device 100 that is equipped with the substrate 50. In the following description, two different manufacturing methods are described as examples of the method for manufacturing the substrate 50 according to the first embodiment. After the two manufacturing methods of the substrate 50 are described, a method for manufacturing the semiconductor device 100 by using the completed substrate 50 will be explained.

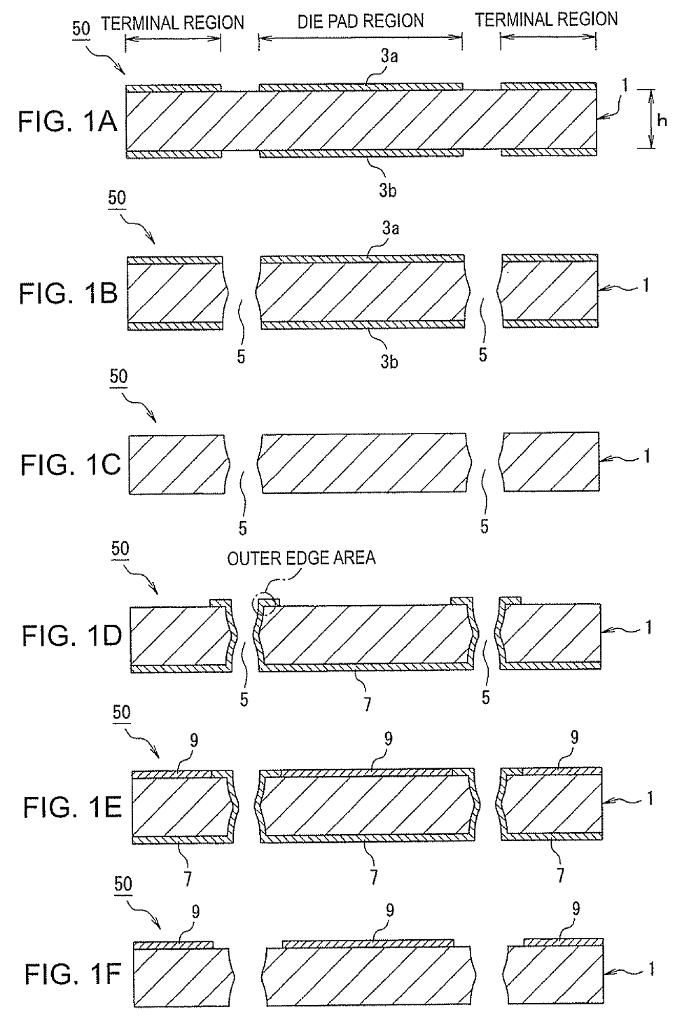

FIGS. 1A through 1F are sectional views showing a first method for manufacturing the substrate 50 according to the first embodiment.

Referring to FIG. 1A, a copper plate 1 (or a copper strip) is prepared. A thickness “h” of the copper plate 1 is for example about 0.01 to 0.30 mm. Other metal plates can be adopted instead of the copper plate 1.

Photoresist is applied onto an upper face and a lower face of the copper plate 1. The photoresist can be either a positive type or a negative type. The photoresist applied onto the upper face and the lower face (in other words, the face facing the opposite direction) of the copper plate 1 are then exposed and developed so as to form resist patterns 3a, 3b. The resist pattern 3a, 3b cover regions where a die pad (hereunder referred as a die pad region), an external terminal (hereunder referred as a terminal region) and an unshown frame (hereunder referred as a frame region) are disposed, but expose the other areas. Here, the resist pattern 3a is provided on the upper face of the copper plate 1 and the resist pattern 3b is provided on the lower face of the copper plate 1.

Referring to FIG. 1B, the copper plate 1 is etched from the upper face side and the lower face side of the copper plate 1 by using the resist patterns 3a, 3b as masks. By this etching process, the copper plate 1 of the areas where are not covered with the resist patterns 3a, 3b are completely removed and a separation trench 5 that penetrates the copper plate 1 is formed. The etching process of the copper plate 1 is conducted for example by wet-etching that adopts a dipping method or a spraying method. As an etching solution, a ferric dichloride solution or an alkaline etching solution (hereinafter referred as an alkaline solution) is for example used. After the separation trench 5 is formed, the resist patterns are removed from the upper face and the lower face of the copper plate 1 as shown in FIG. 1C.

Photoresist is subsequently applied on the upper face and the lower face of the copper plate 1 and a side face of the separation trench 5 (in other words, a face that couples the upper face and the lower face). The photoresist can be either a positive type or a negative type. Referring to FIG. 1D, the applied photoresist is then exposed and developed so as to form a resist pattern 7. The resist pattern 7 covers the periphery and outer edge area of the die pad region, and the periphery and outer edge part of the terminal region on the upper face of the copper plate 1. The resist pattern 7 has an opening area in the center part of the die pad region and in the center part of the terminal region. The resist pattern 7 is also provided so as to cover the whole back face of the copper plate 1 and the whole side face of the separation trench 5.

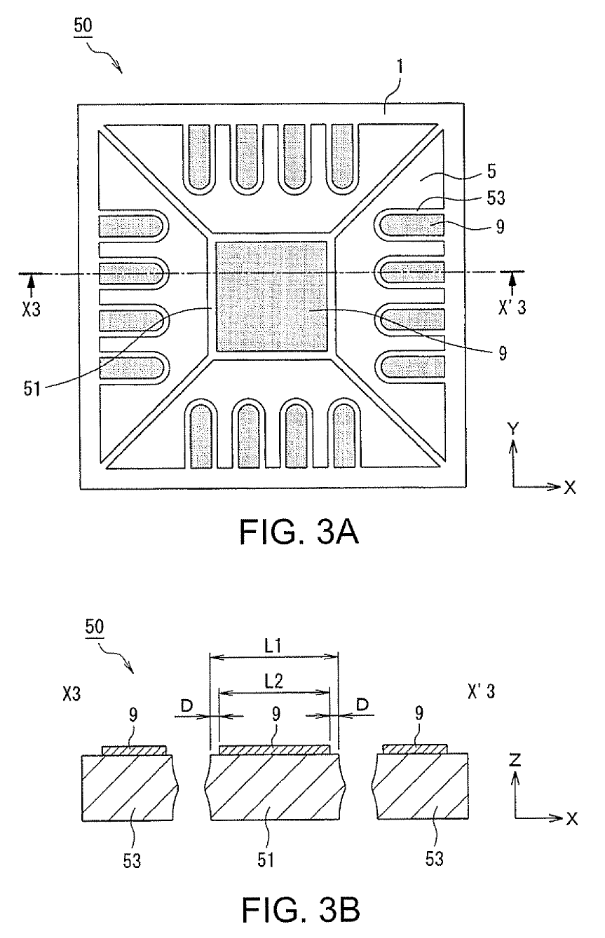

Referring to FIG. 1E, a plated layer 9 is provided in the opening of the resist pattern 7 on the upper face of the copper plate 1 by for example electroplating. Though the plated layer shown in FIG. 1E has a single layer structure, the plated layer can have a multi-layered structure or the single-layer structure. For instance, the plated layer 9 can have a triple layered structure of Ni (a bottom layer)/Pd (a mid layer)/Au (a top layer), a double layered structure of Ni (a bottom layer)/Au (a top layer), or a single layer structure of Ag. Referring to FIG. 1F, the resist pattern is then removed from the copper plate 1. Through the above-described process, the substrate 50 is completed as illustrated in FIGS. 3A and 3B.

The substrate 50 fabricated by the above-described process has a die pad 51 and an external terminal 53 whose area is smaller than that of the die pad 51 when viewed in plan. The external terminal 53 is provided in the plural number and the terminals are arranged around the die pad 51. Therefore the substrate 50 can be used as a lead frame for QFN. On an upper face of the die pad 51, the plated layer 9 is disposed in the center part area, but the outer edge part of the die pad 51 is not contacted with the plated layer 9. Moreover, the plated layer 9 is not provided in the periphery of the die pad 51. In the same manner, on an upper face of the external terminal 53, the plated layer 9 is disposed in the center part area, but the outer edge area of the external terminal 53 is not contacted with the plated layer 9. Moreover, the plated layer 9 is not provided in the periphery of the external terminal 53.

Referring to FIG. 3B, for example, a dimensional length along the X axis direction of the die pad 51 is denoted as L1, and a dimensional length of the plated layer 9 on the die pad 51 is denoted as L2, here L1>L2. A distance D (=(L1−L2)/2) between the outer edge of the die pad 51 and the plated layer is for example 1 to 50 μm.

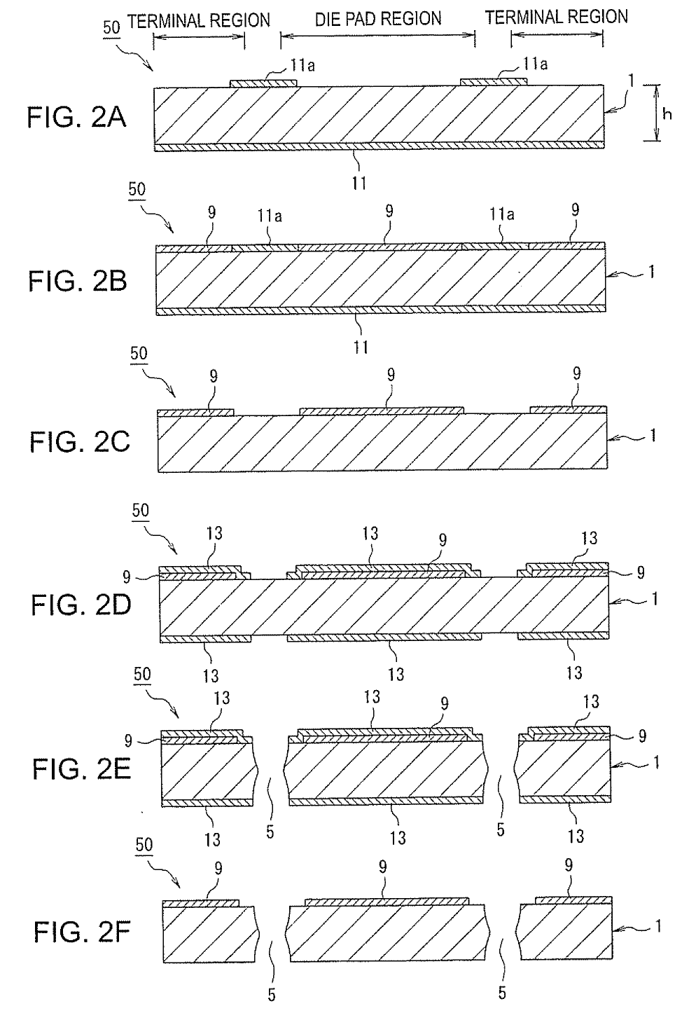

Another method for manufacturing the substrate 50 will be now described with reference to FIG. 2.

FIGS. 2A through 2G are sectional views showing a second method for manufacturing the substrate 50 according to the first embodiment.

Referring to FIG. 2A, the copper plate 1 is prepared. Photoresist 11 is then applied onto the upper face and the lower face of the copper plate 1. The photoresist 11 can be either a positive type or a negative type. The photoresist 11 is then exposed and developed so as to form a resist pattern 11a on the upper face of the copper plate 1. The resist pattern 11a exposes the center part area of the die pad region and the center part area of the terminal region but covers the other areas (including the outer edge area and the periphery of the die pad region, and the outer edge area and the periphery of the terminal region). In other words, the resist pattern 11a is formed such that the size of the opening provided in the die pad region is smaller than the actual size of the die pad region and the size of the opening provided in the terminal region is smaller than the actual size of the terminal region. Referring to FIG. 2A, an exposure treatment is not performed to the back face of the copper plate 1 in the formation process of the resist pattern 11a. The whole back face of the copper plate 1 remains being covered with the photoresist 11 at this point.

Referring to FIG. 2B, the plated layer 9 is provided by, for example, electroplating in an area exposed from the resist pattern 11a on the upper face of the copper plate 1. After the plated layer 9 is formed, the resist pattern is removed from the upper face of the copper plate 1 and the photoresist is removed from the lower face of the copper plate as shown in FIG. 2C. Photoresist is subsequently applied onto the upper face and the lower face of the copper plate 1. The photoresist can be either a positive type or a negative type.

Referring to FIG. 2D, the photoresist that is applied on the upper face and the lower face of the copper plate 1 is then exposed and developed so as to form a resist pattern 13 on the upper face and the lower face of the copper plate. The resist pattern 13 covers the die pad region and the terminal region but exposes the other areas. In this way, the plated layer 9 in the die pad region and the plated layer 9 in the terminal region are completely covered and protected by the resist pattern 13. In other words, the resist pattern 13 is disposed so as to cover the upper face (the face opposite to the lower face that contacts with the copper plate 1) and the side face of the plated layer 9.

Referring to FIG. 2E, the copper plate 1 is etched from the upper face side and the lower face side by using the resist patterns 13 as a mask. By this etching process, the copper plate 1 of the area where is not covered with the resist pattern 13 is completely removed and the separation trench 5 is formed. This etching of the copper plate 1 can be performed with the same conditions as those of the etching of the copper plate 1 described above with reference to FIG. 1B. After the separation trench 5 is formed, the resist pattern is removed from the upper face and the lower face of the copper plate 1 as shown in FIG. 2F. Through the above-described process, the substrate 50 is completed as illustrated in FIGS. 3A and 3B.

In the substrate 50 (hereinafter also referred as the lead frame) that is manufactured by the methods described above with reference to FIG. 1 and FIG. 2, it is possible to prevent the eaves made of the plated layer 9 from being formed. Consequently the rigidity of the plated layer 9 as a whole can be increased, and tips of the plated layer 9 will not be broken or come off. In addition, chances of burr formation are reduced, which contributes to the stabilization of the planar shapes of the die pad 51 and the external terminal 53.

A method for manufacturing the semiconductor device 100 by attaching an integrated circuit (IC) element on the lead frame 50 for QFN will be now described.

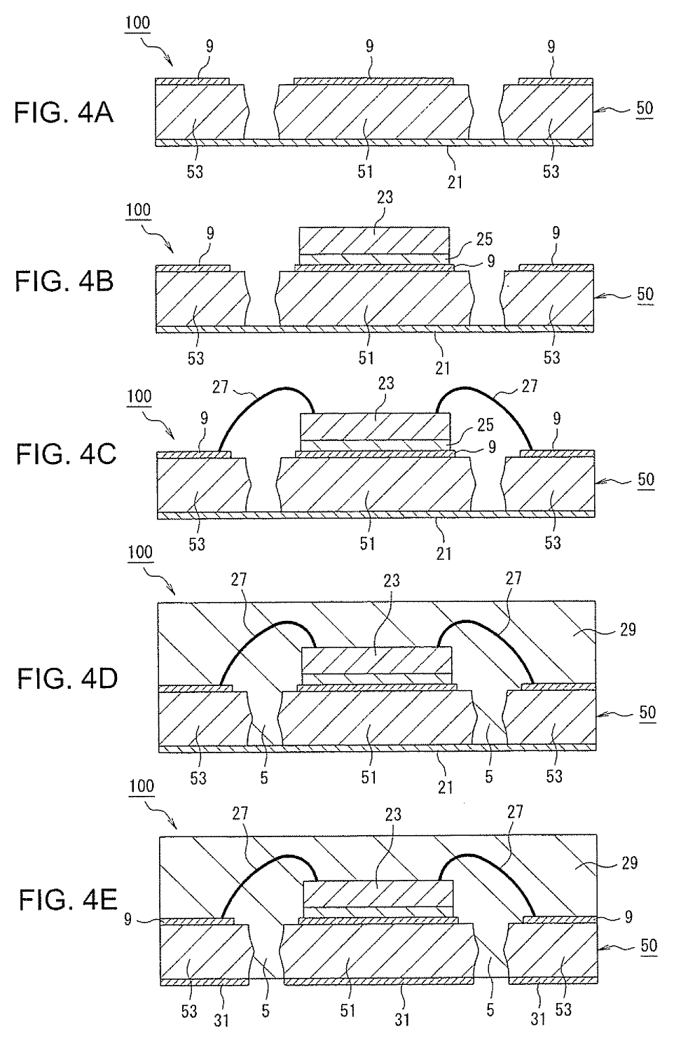

FIGS. 4A through 4E are sectional views showing a method for manufacturing the semiconductor device 100 according to the first embodiment. Referring to FIG. 4A, a reinforcing tape 21 is attached (for example laminated) to the whole back face of the lead frame 50 in order to increase the strength of the lead frame 50.

Referring to FIG. 4B, the die pad 51 is recognized by using a particular part of the lead frame 50 (for example, when a planer shape of the die pad is a rectangle, four vertexes of the rectangle) as a guide, and an IC element 23 is aligned in the recognized die pad 51. The IC element 23 is then attached to the die pad 51 as the IC element is aligned (a die attaching step). In this die attaching step, the IC element 23 is adhesively bonded with the die pad 51 with an adhesive 25. The adhesive 25 used here can be a sheet type adhesive or a paste form adhesive.

Referring to FIG. 4C, a pad terminal which is disposed on an active face of the IC element 23 is coupled to the upper face of the external terminal 53 through for example a gold wire 27 (a wire bonding step). Here, the external terminal 53 can be recognized by using a particular part of the lead frame 50 (for example, the four vertexes of the die pad 51 as described above) as a guide, and one end of the gold wire 27 can be connected with the recognized external terminal 53.

Referring to FIG. 4D, the lead frame 50 including the IC element 23 and the gold wire 27 are sealed with a mold resin 29 (a resin sealing step). In the resin sealing step, a cavity is placed on the upper face side (or over the reinforcing tape 21) of the lead frame 50 including the IC element 23 and the like, the inside of the cavity is depressurized, and the mold resin 29 is supplied into the depressurized cavity. When the resin is supplied under a reduced pressure, the mold resin 29 can be efficiently provided into the cavity and the separation trench 5 can be filled with the mold resin 29 without leaving a space in the separation trench 5 as shown in FIG. 4D.

The reinforcing tape 21 is then removed from the back face of the lead frame 50. Referring to FIG. 4E, a plated layer 31 is provided on the back face of the lead frame 50. The plated layer 31 is formed by for example electroplating. Though the plated layer 31 shown in FIG. 4E has a single layer structure, the plated layer can have a multi-layered structure or the single-layer structure. For instance, the plated layer 31 can have a triple layered structure of Ni (a bottom layer)/Pd (a mid layer)/Au (a top layer), a double layered structure of Ni (a bottom layer)/Au (a top layer), or a single layer structure of solder. After the formation of the plated layer, the mold resin 29 is diced into each resin package and unnecessary parts of the resin which cannot become a product is cut out and removed in a dicing step. Through the above-described process, the semiconductor device 100 that has for example the QFN structure is completed.

According to the first embodiment, it is possible to prevent the “eaves” that is made of the plated layer 9 from being formed so that the rigidity of the plated layer 9 as a whole can be increased and tips of the plated layer 9 will not be broken or come off. Therefore it is possible to prevent the migration failure due to the brake or peel off of the plated layer 9 from happening. In addition, chances of burr formation are reduced, which contributes to the stabilization of the planar shapes of the die pad 51 and the external terminal 53. Therefore in the wire-bonding process, for example, a jointing area of the external terminal 53 can be precisely recognized and one end of the gold wire 27 can be appropriately connected to the area. In this way, it is possible to increase the manufacturing efficiency of the semiconductor device 100. Moreover, in the resin sealing step, the “eaves” which can be an obstacle in the sealing step does not exist so that the mold resin 29 can easily fill into the separation trench 5. Thereby it is possible to prevent a void space and the like from being generated in the resin package, which increases the reliability of the resin package.

### Second Embodiment

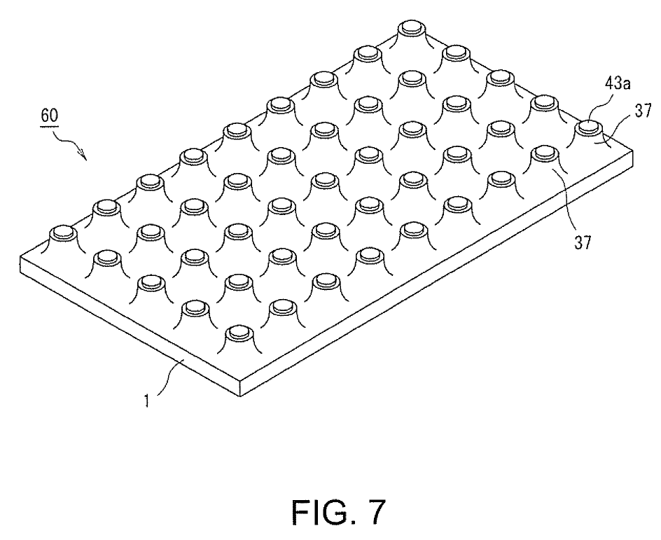

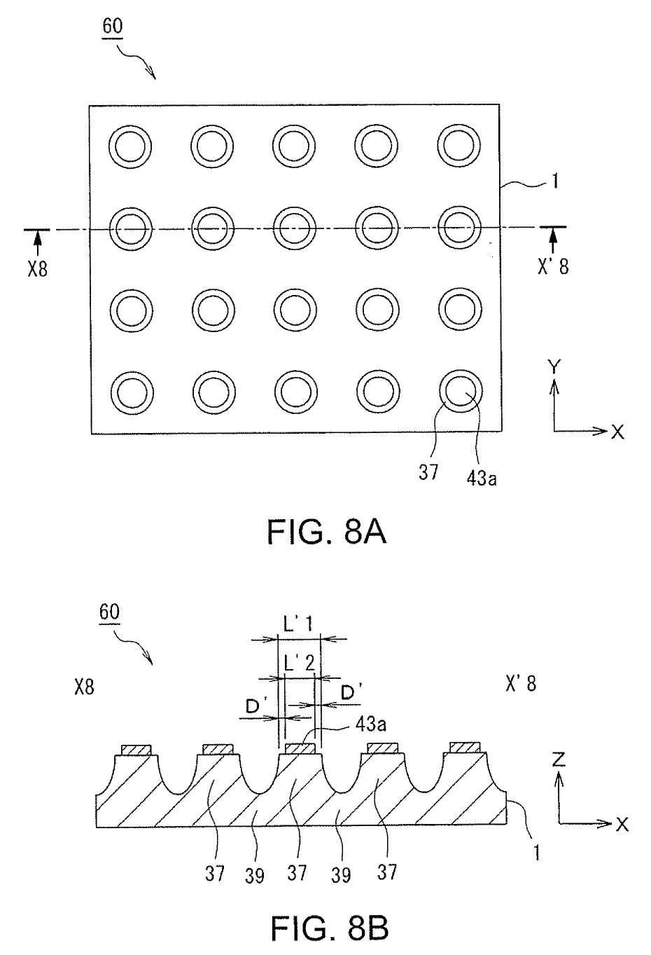

The lead frame for the QFN has been described as an example in the above first embodiment. However, the invention is not limited to the above-described example, but can be applied to for example a substrate that has no product segment and has a high versatility. Referring to FIG. 7 and FIGS. 8A and 8B, such substrate has a post 37 which is provided in the plural number and arranged in more than one line both in a lengthwise direction and a crosswise direction. The posts 37 can be used as a die pad, an external terminal and the like. An example of such application will be described in a hereunder given second embodiment.

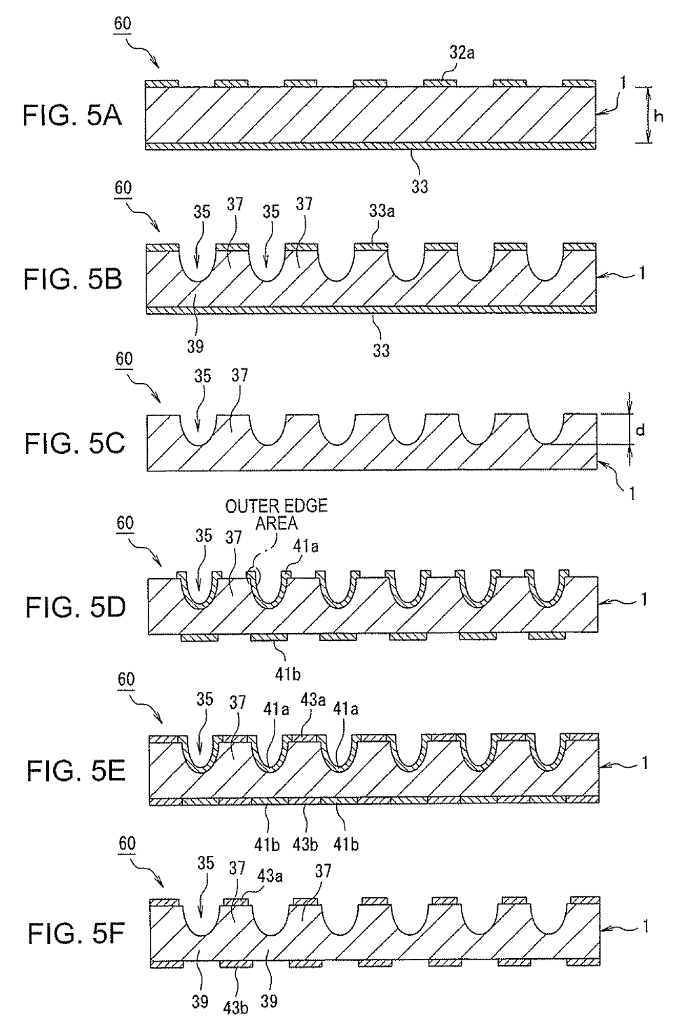

FIGS. 5A through 5F are sectional views showing a first method for manufacturing a substrate 60 according to the second embodiment.

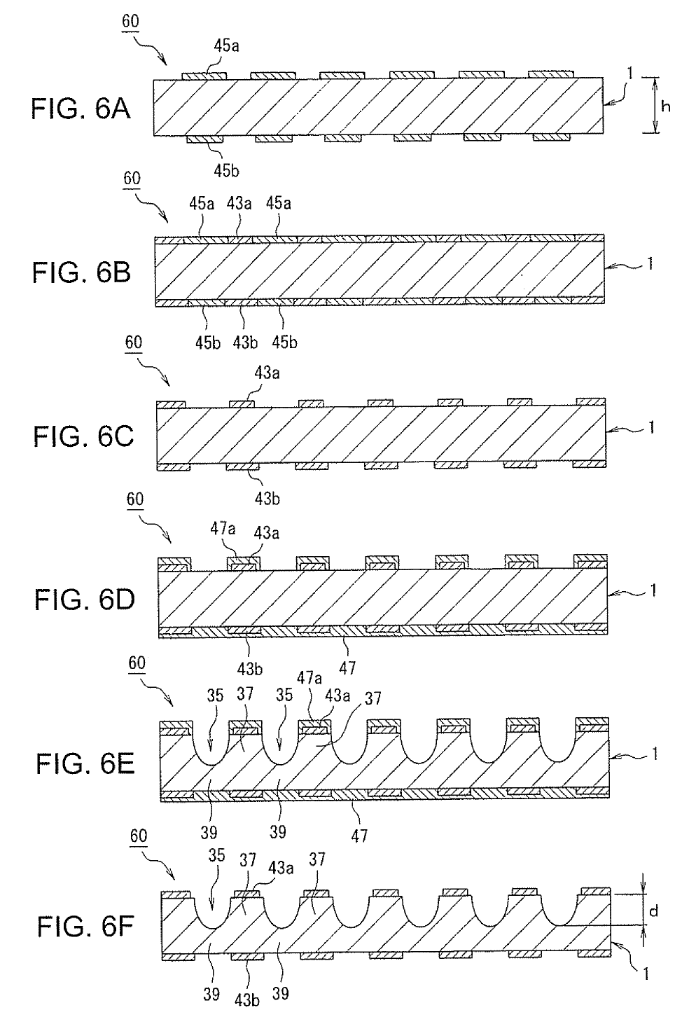

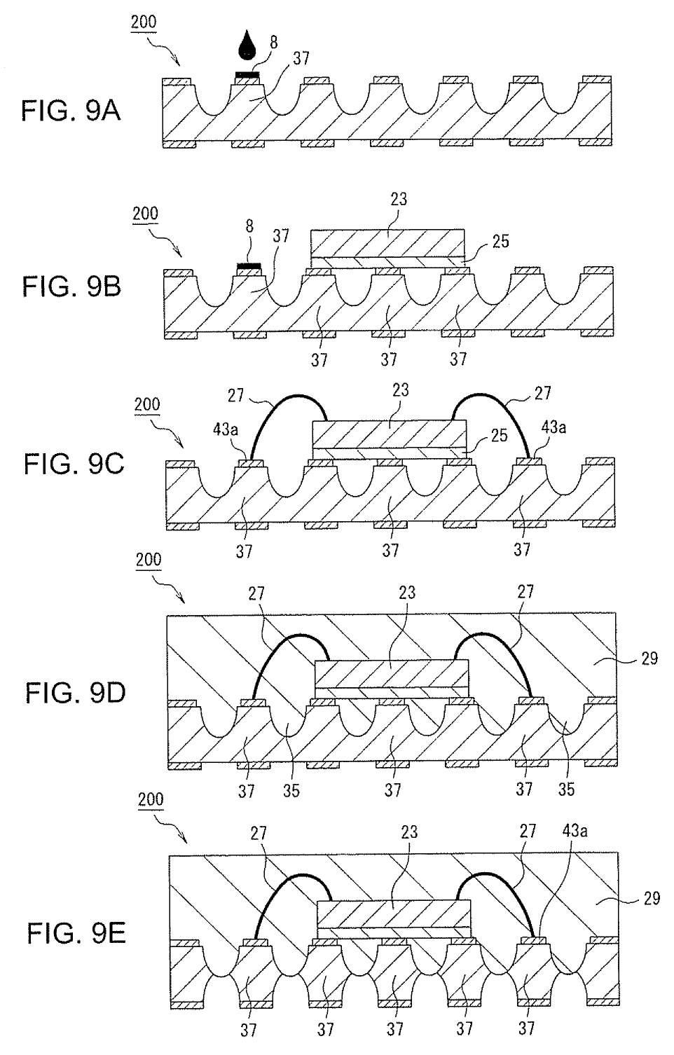

In the second embodiment, a method for manufacturing the substrate 60 will be described followed by a description of a method for manufacturing a semiconductor device 200 by using the substrate 60. In the second embodiment, two different manufacturing methods are described as examples of the method for manufacturing the substrate 60 with reference to FIGS. 5A to 5F and FIGS. 6a to 6F respectively. After the two manufacturing methods of the substrate 60 are described, the method for manufacturing the semiconductor device 200 will be explained with reference to FIGS. 9A to 9F.

FIGS. 5A through 5F are sectional views showing the method for manufacturing the substrate 60 according to the second embodiment. Referring to FIG. 5A, the copper plate 1 is provided. Photoresist 33 is applied onto the upper face and the lower face of the copper plate 1. The photoresist 33 can be either a positive type or a negative type. The photoresist 33 that is applied on the upper face of the copper plate 1 is then exposed and developed so as to form a resist pattern 33a. The resist pattern 33a covers a region where the posts are formed and exposes the other areas. Referring to FIG. 5A, here the resist pattern 33a is provided only on the upper face of the copper plate 1 and the whole lower face of the copper plate 1 remains being covered with the unexposed photoresist 33 at this point.

The copper plate 1 is subsequently etched by using the resist pattern 33a as a mask so as to form a concave portion 35 on the upper face side of the copper plate 1. By forming a plurality of the concave portions 35, a plurality of the posts 37 is provided on the upper face of the copper plate 1. In this etching step, the concave portions 35 are formed only in the upper face of the copper plate 1 thereby a connecting part 39 that couples the posts 37 in the crosswise direction when viewed in section is left on the lower face side of the copper plate 1. More specifically, the etching process is stopped before parts of the copper plate 1 existing between the posts 37 completely disappear (are penetrated) by the etching. Through this half-etching process, the posts 37 are coupled each other with the part that exists at a some point from the bottom face of the concave portion 35 to the lower face of the copper plate 1.

The above mentioned half-etching process of the copper plate 1 described with reference to FIG. 5D is conducted for example by wet-etching that adopts a dipping method or a spraying method. As an etching solution, a ferric dichloride solution or an alkaline solution is for example used. As for a depth of the concave portion 35, the depth “d” of the concave portion 35 can be given by for example d=0.4×h to 0.6×h, where “h” is a thickness of the copper plate 1. For instance, the concave portion 35 having a depth of 0.1 mm can be provided on the upper face side of the copper plate 1 by adjusting a treating time of the wet-etching process.

The resist pattern 33a is subsequently removed from the upper face of the copper plate 1 and the photoresist 33 is removed from the lower face at the same time. Referring to FIG. 5C, the upper face and the lower face of the copper plate 1 are exposed. Photoresist is then applied onto the upper face and the lower face of the copper plate 1. The photoresist can be either a positive type or a negative type.

Referring to FIG. 5D, the photoresist that is applied on the upper face and the lower face of the copper plate 1 is then exposed and developed so as to form resist patterns 41a, 41b on the upper face and the lower face of the copper plate 1 respectively. The resist patterns 41a, 41b expose a center part in the upper face of the post 37 but cover the other areas (including an outer edge area and a peripheral area of the post 37). More specifically, the resist pattern 41a covers the bottom face and a side face of the concave portion 35, and the resist pattern 41b is provided in the area opposing the concave portion 35 on the lower face of the copper plate 1.

Referring to FIG. 5E, plated layers 43a, 43b are provided by for example electroplating in the areas where are exposed from the resist patterns 41a, 41b (in other words, in the center part area of the post 37) on the copper plate 1. Here, the plated layer 43a is disposed on the upper face of the copper plate 1, and the plated layer 43b is disposed on the lower face of the copper plate 1. Though the plated layers 43a, 43b shown in FIG. 5E have a single layer structure, the plated layers 43a, 43b can have a multi-layered structure or the single-layer structure. For instance, the plated layers 43a, 43b can have a triple layered structure of Ni (a bottom layer)/Pd (a mid layer)/Au (a top layer), a double layered structure of Ni (a bottom layer)/Au (a top layer), or a single layer structure of Ag.

Referring to FIG. 5F, the resist pattern is then removed from the upper face and the lower face of the copper plate 1. Through the above-described process, the substrate 60 as shown in FIG. 7 and FIGS. 8A and 8B is completed.

The substrate 60 that is fabricated according to the above described method has the plurality of the posts 37 which are arranged in lines in the lengthwise and crosswise directions when viewed in plan. Each post 37 is coupled each other on the lower face side of the copper plate 1. A planer shape of the post 37 can be for example a precise circle or other shapes (for example polygons). In this way, the posts 37 can be used as a die pad or an external terminal on which various elements having a wide variety of functions and shapes can be mounted. Moreover the posts 37 can be used as the die pad or the external terminal depending on a shape and size of an IC fixing area or a shape and size of a passive element. Thereby it is not necessary to prepare a specific die pad, lead frame and substrate (interposer or the like) which are especially made depending on a type of the IC element in order to assemble the semiconductor device 200. This means that a single type of the substrate for mounting an element and an external terminal can be adopted for various types of elements without limiting layouts (arrangements) of the pad terminal according to the embodiment. In this way, it is possible to reduce the manufacturing cost of the substrate and the semiconductor device that is equipped with the substrate.

Referring to FIG. 8A and FIG. 8B, in the substrate 60, the plated layer 43a is disposed in the center part of the upper face of each post 37 but not provided in the edge area of the post. Referring to FIG. 8B, for example, a dimensional length along the X axis direction (or a diameter) of the post 37 is denoted as L′1, and a dimensional length of the plated layer 43a on the post 37 is denoted as L′2, here L′1>L′2. A distance D′ (=(L′1−L′2)/2) between the outer edge of the post 37 and the plated layer 43a is for example 1 to 50 μm.

Another method for manufacturing the substrate 60 will be now described with reference to FIGS. 6A to 6F.

FIGS. 6A through 6F are sectional views showing a second method for manufacturing the substrate 60 according to the second embodiment.

Referring to FIG. 6A, the copper plate 1 is prepared. Photoresist is then applied onto the upper face and the lower face of the copper plate 1. The photoresist can be either a positive type or a negative type. The photoresist provided on the upper face of the copper plate 1 is then exposed and developed so as to form a resist pattern 45a. The resist pattern 45a exposes the center part area of the post but covers the other areas (including the outer edge area and the periphery of the post). The photoresist provided on the lower face of the copper plate 1 is also exposed and developed so as to form a resist pattern 45b. The resist pattern 45b exposes the areas where the posts are formed but covers the rest of the area. Here, a size of an opening in the resist pattern 45a is made smaller than a size of an opening in the resist pattern 45b. In this way, the outer edge of the post is exposed only on the upper face side of the copper plate 1.

Referring to FIG. 6B, a plated layer 43a is provided in an area where is exposed from the resist pattern 45a on the upper face of the copper plate 1, and a plated layer 43b is provided in an area where is exposed from the resist pattern 45b on the lower face of the copper plate 1. The plated layers 43a, 43b are formed by for example electroplating. Though the plated layer 43a, 43b shown in FIG. 6B have a single layer structure, the plated layers 43a, 43b can have a multi-layered structure or the single-layer structure, as described above with reference to FIG. 5E.

After the formation of the plated layers 43a, 43b, the resist patterns are removed from the upper face and the lower face of the copper plate 1 as shown in FIG. 6C. Photoresist is subsequently applied onto the upper face and the lower face of the copper plate 1. The photoresist can be either a positive type or a negative type.

Referring to FIG. 6D, the photoresist provided on the upper face of the copper plate 1 is then exposed and developed so as to form a resist pattern 47a only on the upper face of the copper plate 1. The resist pattern 47a covers the areas where the posts are formed but exposes the other areas. The plated layer 43a that is disposed on the upper face of the copper plate 1 is completely covered and protected by the resist pattern 47a. In other words, the resist pattern 47a covers the upper face (the face opposite to the lower face that contacts with the copper plate 1) and the side face of the plated layer 43a. The photoresist 47 that is provided on the lower face of the copper plate 1 remains unexposed at this point.

Referring to FIG. 6E, the copper plate 1 is subsequently etched by using the resist pattern 47a as a mask so as to form the concave portion 35 on the upper face side of the copper plate 1. By forming a plurality of the concave portions 35, a plurality of the posts 37 is provided on the upper face of the copper plate 1. In this etching step, the concave portions 35 are formed only in the upper face of the copper plate 1 thereby a connecting part 39 that couples the posts 37 in the crosswise direction when viewed in section is left on the lower face side of the copper plate 1. More specifically, the etching process is stopped before parts of the copper plate 1 existing between the posts 37 completely disappear (are penetrated) by the etching. Through this half-etching process, the posts 37 are coupled each other with the part that exists at a some point from the bottom face of the concave portion 35 to the lower face of the copper plate 1. The half-etching process shown in FIG. 6E can be conducted at the same conditions as those of the half-etching process of the copper plate 1 described above with reference to FIG. 5B. After the concave portions 35 are formed, the resist patterns are removed from the upper face and the lower face of the copper plate 1 as shown in FIG. 6F. Through the above-described processes, the substrate 60 as illustrated in FIG. 7 and FIGS. 8A and 8B is completed.

In the substrate 60 that is manufactured by the methods described above with reference to FIGS. 5A to 5F and FIGS. 6A to 6F, the eaves that is made of the plated layer 43a is not formed. Consequently the rigidity of the plated layer 43a as a whole can be increased, and tips of the plated layer 43a will not be broken or come off. In addition, chances of burr formation are reduced, which contributes to the stabilization of the planar shapes of the post 37.

A method for manufacturing the semiconductor device 200 by attaching an IC element and a passive element on the substrate 60 will be now described.

FIGS. 9A through 9E are sectional views showing a method for manufacturing the semiconductor device 200 according to the second embodiment. Referring to FIG. 9A, a recognition mark 8 is provided by coloring the upper face (front face) of the post 37 that is located in a desired position. The recognition mark 8 is used as a guide in a hereunder described die attaching step, a wire-bonding step and the like in order to recognize a position (coordinate) in the substrate 60. The recognition mark 8 is formed by coloring the upper face (front face) of the post 37 which is placed at a desired position by using for example an inkjet method, a printing method, a dispensing method or a laser marking method. When the recognition mark 8 is provided by the inkjet method, a heat resistant multicolor ink, a multi color plating material or the like can be used as a coloring material.

Referring to FIG. 9B, the adhesive 25 is applied onto a lower face of the IC element 23. The IC fixing area is identified by using the recognition mark 8, and the IC element 23 is aligned and disposed in the identified IC fixing area. The lower face (a face opposing the face where the pad terminal of the IC element 23 is provided) of the IC element 23 is placed onto the posts 37 as the IC element is aligned, and the IC element is fixed there (a die attaching step).

Referring to FIG. 9C, an upper face of the post 37 (in other words, a second post) that is located in an area other than the IC fixing area and a pad terminal that is disposed on the front face of the IC element 23 are coupled with for example the gold wire 27. Here, the second post 37 which serves as the external terminal is recognized by using the recognition mark 8, and one end of the gold wire 27 is coupled to the recognized second post 37 (a wire-bonding step).

Referring to FIG. 9D, the whole upper part of the substrate 60 including the IC element 23, the gold wire 27 and the post 37 is sealed with the mold resin 29 (a resin sealing step). In the resin sealing step, for example, a cavity is placed on the upper face side of the substrate 60 and over the IC element 23 and the like, the inside of the cavity is depressurized, and the mold resin 29 is supplied into the depressurized cavity. When the resin is supplied under a reduced pressure, the mold resin 29 can be efficiently provided into the cavity and the concave portion 35 can be filled with the mold resin 29 without leaving a space in the separation trench as shown in FIG. 9D.

The connecting part 39 that couples the posts 37 is then removed by etching the substrate 60 from the lower face side. The etching of the connecting part 39 is performed by using for example a ferric dichloride solution or an alkaline solution which is also used in the formation of the concave portion 35. Referring to FIG. 9E, the two adjacent posts 37 are electrically separated after the etching, and the individual second post 37 to which one end of the gold wire 27 is coupled can be used as an electrically independent external terminal. Furthermore, the upper face part of each post 37 is fixed with the mold resin 29 thereby the position of the post 37 is retained at the original position even after the connecting part is removed,

A dicing blade 79 which is not illustrated in the drawings is contacted with the mold resin 29, and the mold resin 29 is cut according to a product profile (a dicing step). In this way, the mold resin 29 is divided into an individual resin package piece and unnecessary parts of the resin which cannot become a product are removed at the same time. Through this dicing step, the semiconductor device 200 is completed.

According to the second embodiment, the rigidity of the plated layer 43a as a whole can be increased, and tips of the plated layer 43a will not be broken or come off in the same way as the first embodiment. Therefore it is possible to prevent the migration failure due to the brake or peel off of the plated layer 43a from happening. In addition, chances of burr formation are reduced, which contributes to the stabilization of the planar shapes of the post 37. Therefore in the wire-bonding process, for example, a jointing area on the post 37 can be precisely recognized and one end of the gold wire 27 can be appropriately connected to the area. In this way, it is possible to increase the manufacturing efficiency of the semiconductor device 200.

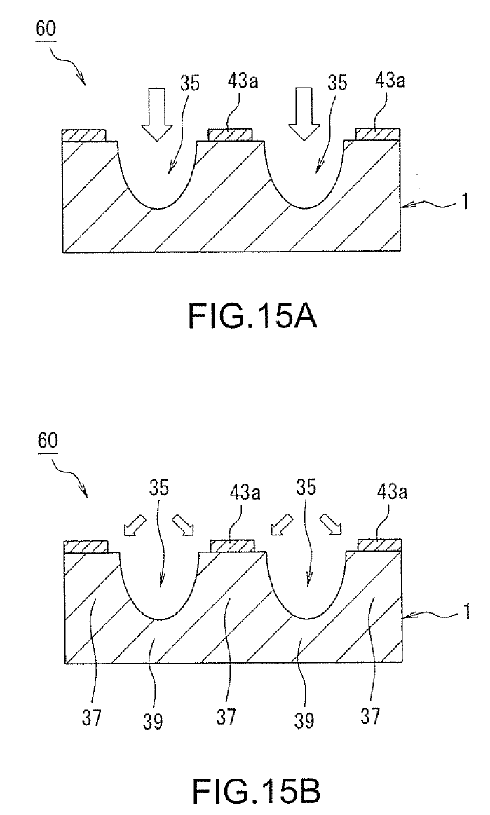

Moreover, according to the second embodiment, the “eaves” which can be an obstacle in the sealing step does not exist so that the mold resin 29 can easily fill into the concave portion 35 for example as indicated by the arrow in FIG. 15A. Thereby it is possible to prevent a void space and the like from being generated in the resin package, and the reliability of the resin package can be increased. Moreover, the copper plate 1 is exposed in the periphery of the post 37 as indicated by for example the arrows in FIG. 15B thereby it is possible to increase the contact area of Cu and the resin on the upper face of the post 37. Consequently adhesion between the substrate 60 and the mold resin can be increased. Generally adhesion between a resin and a noble metal (such as a plated layer of Au or the like) is low. However it is possible to increase the exposed area of Cu in the upper face of the copper plate 1 according to the first, second and hereunder described third embodiments so that the adhesion of the resin and the substrate can be increased.

According to the second embodiment, the substrate 60 has a specification for mounting various types of elements and is standardized without increasing constraints on layouts (arrangements) of pad terminals of the IC element. In other words, according to the embodiment, it is possible to provide the substrate 60 which is highly versatile for various types of elements. In this way, the manufacturing costs of the semiconductor device 200 equipped with the substrate 60 can be reduced.

Examples of a chip size, the number of terminals under the chip (in other words, the number of posts 37), the maximum number of external terminals and a dimension of the package, which can be applied to the semiconductor device 200 equipped with the substrate 60 according to the second embodiment, are listed in Table 1 below.

TABLE 1

| | | The number of | The maximum | Package |
|---|---|---|---|---|
| Pitch | Chip Size | terminals | number of external | Dimension |
| (mm) | (mmSQ) | under Chip | terminals | (mm) |
| 0.5 | 1 | 4 | 16 | 2.5 |
| 0.5 | 2 | 16 | 36 | 3.5 |
| 0.5 | 3 | 36 | 64 | 4.5 |
| 0.5 | 4 | 64 | 100 | 5.5 |
| 0.5 | 5 | 100 | 144 | 6.5 |
| 0.5 | 6 | 144 | 196 | 7.5 |
| 0.5 | 7 | 196 | 256 | 8.5 |

“Pitch” in Table 1 means a distance between two adjacent posts in the same row or the same column. The distance is measured for example from the center of one post to the center of the other post (which is located next to each other). As shown in Table 1 above, the pitch is for example about 0.5 mm. “Chip size” is a chip size of the IC element sealed in the resin package. The maximum number of external terminals is the largest number of posts 37 which can be sealed with resin as a resin package. “Package dimension” is a lengthwise length or a crosswise length of the resin package when viewed in plan. Note that the examples in Table 1 are the case where the IC element and the resin package have a square shape when they are viewed in plan.

### Third Embodiment

In the above second embodiment, the substrate having the connecting part that couples the two adjacent posts in the crosswise direction when viewed in section has been described as an example. However the invention is not limited to this. For instance, the plurality of the posts which are arranged in more than one line both in the crosswise direction and the lengthwise direction when viewed in plan can be coupled each other through a supporting substrate instead of the connecting part. Such example will be described in a hereunder third embodiment of the invention.

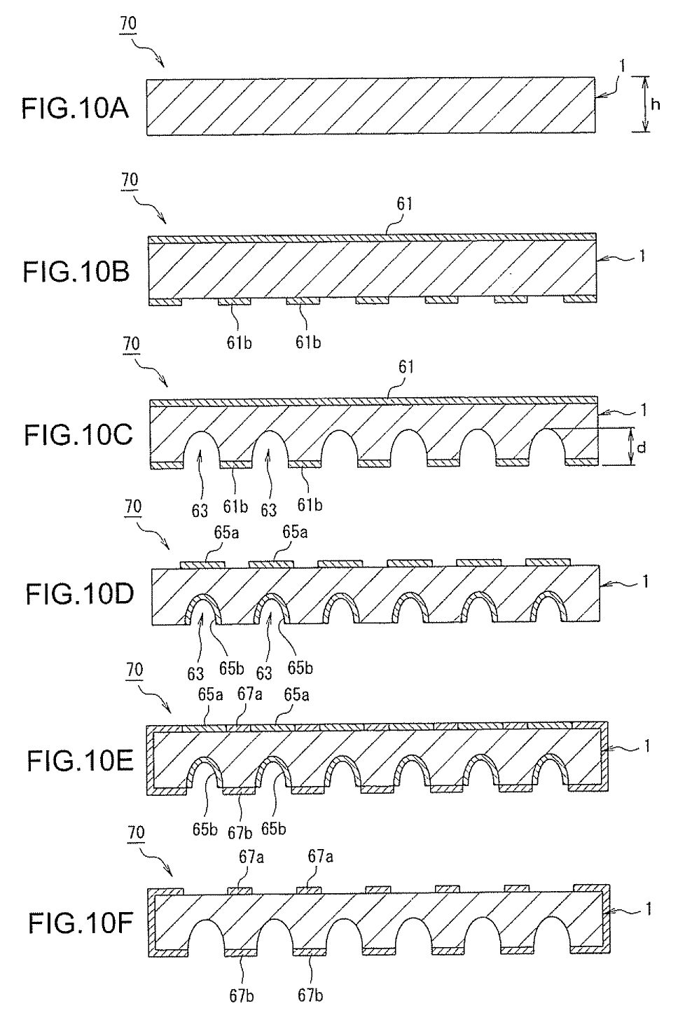

FIGS. 10A through 12C illustrate a method for manufacturing a substrate 70 according to the third embodiment. Referring to FIG. 10A, the copper plate 1 is prepared. Referring to FIG. 10B, a photoresist 61 is applied onto the upper face and the lower face of the copper plate 1. The photoresist 61 can be either a positive type or a negative type. The photoresist 61 provided on the lower face of the copper plate 1 is then exposed and developed so as to form a resist pattern 61b. The resist pattern 61b covers the area where the post is formed but exposes the other areas. Referring to FIG. 10B, here, the resist pattern 61b is provided only on the lower face of the copper plate 1. Unexposed photoresist remains on the upper face of the copper plate 1 at this point.

The copper plate 1 is etched by using the resist pattern 61b as a mask. Referring to FIG. 10C, a concave portion 63 is formed on the lower face side of the copper plate 1 through the etching. The above mentioned etching process of the copper plate 1 is conducted for example by wet-etching that adopts a dipping method or a spraying method. As an etching solution, a ferric dichloride solution or an alkaline solution is for example used. As for a depth of the concave portion 63, the depth “d” of the concave portion 63 can be given by for example d=0.4×h to 0.6×h, where “h” is the thickness of the copper plate 1. For instance, the concave portion 63 having a depth of 0.1 mm can be provided on the upper face side of the copper plate 1 by adjusting a treating time of the wet-etching process. The photoresist 61 and the resist pattern 61b are then removed from the copper plate 1.

Photoresist is subsequently applied onto the upper face and the lower face of the copper plate 1. The photoresist can be either a positive type or a negative type. The photoresist provided on the upper face and the lower face of the copper plate 1 is then exposed and developed so as to form resist patterns. Referring to FIG. 10D, a resist pattern 65a that exposes the center part area of the post but covers the other areas (including the outer edge area and the periphery of the post) is formed on the upper face of the copper plate 1. At the same time, a resist pattern 65b that exposes the area where the post is provided but covers the other area is formed on the lower face of the copper plate 1. In other words, the resist pattern 65b is formed so as to cover a bottom face and a side face of the concave portion 63.

Referring to FIG. 10E, plated layers 67a, 67b are provided by for example electroplating in the areas where are exposed from the resist patterns 65a, 65b (in other words, the area where the post is formed) on the copper plate 1. Though the plated layers 67a, 67b shown in FIG. 10E have a single layer structure, the plated layers 67a, 67b can have a multi-layered structure or the single-layer structure. For instance, the plated layers 67a, 67b can have a triple layered structure of Ni (a bottom layer)/Pd (a mid layer)/Au (a top layer), a double layered structure of Ni (a bottom layer)/Au (a top layer), or a single layer structure of Ag. Referring to FIG. 10F, the resist patterns are then removed from the upper face and the lower face of the copper plate 1.

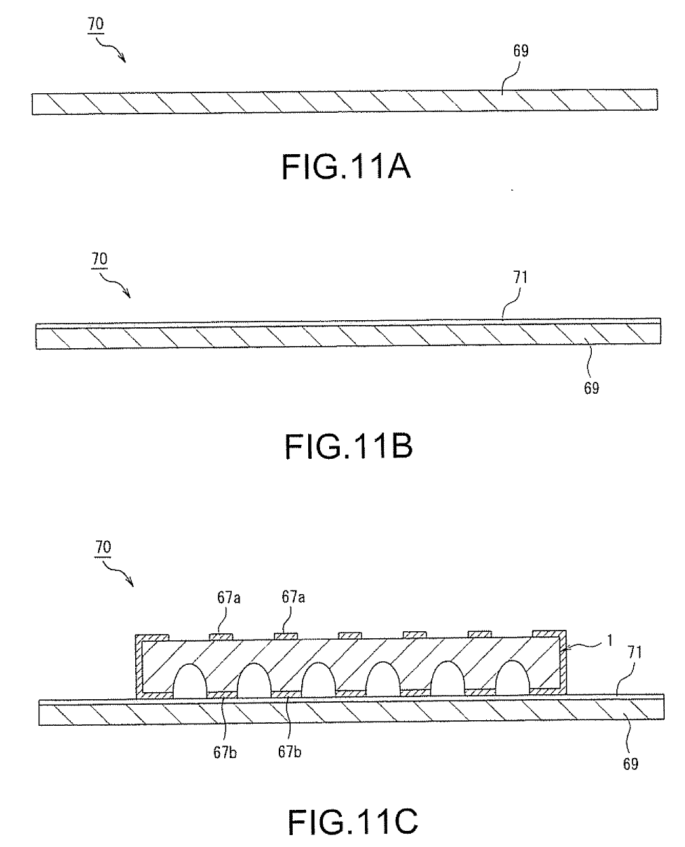

Referring to FIG. 11A, a supporting substrate 69 is prepared before, after or simultaneously with the above-described plating process and the like. Referring to FIG. 11B, an adhesive 71 is applied onto the upper face of the supporting substrate 69. The supporting substrate 69 is for example a glass substrate. The adhesive 71 is for example a solder resist, an ultraviolet curable adhesive (or UV adhesive), a thermosetting adhesive or the like. Referring to FIG. 11C, the lower face of the copper plate 1 to which the plating treatment is performed is then pressed and jointed onto the upper face of the supporting substrate 69 on which the adhesive 71 has been applied.

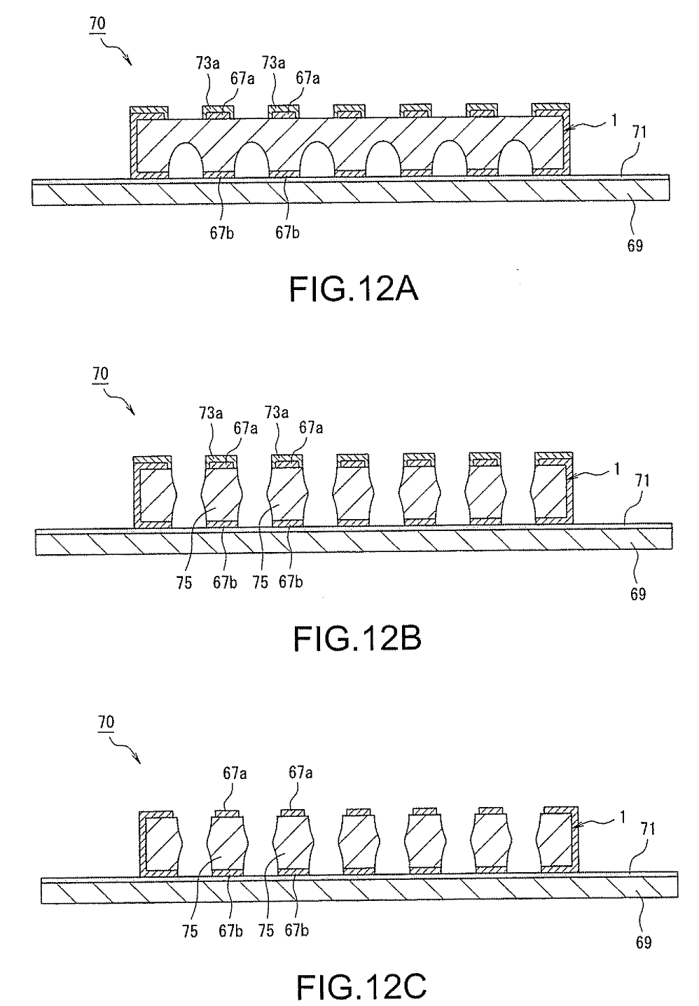

Referring to FIG. 12A, a resist pattern 73a that covers the areas where the posts are formed but exposes the other areas is formed on the upper face of the copper plate 1. The plated layer 67a that is disposed on the upper face of the copper plate 1 is completely covered and protected by the resist pattern 73a. In other words, the resist pattern 73a covers the face (the face opposite to the lower face that contacts with the copper plate 1) and the side face of the plated layer 67a. The copper plate 1 is subsequently etched by using the resist pattern 73a as a mask till the copper plate 1 is penetrated from the upper face side to the lower face side. Through the etching process, a plurality of the posts 75 is formed as shown in FIG. 12B. Referring to FIG. 12C, after the plurality of the posts 75 is provided, the resist pattern is removed from the upper face of the post 75. Through the above-described processes, the substrate 70 is completed.

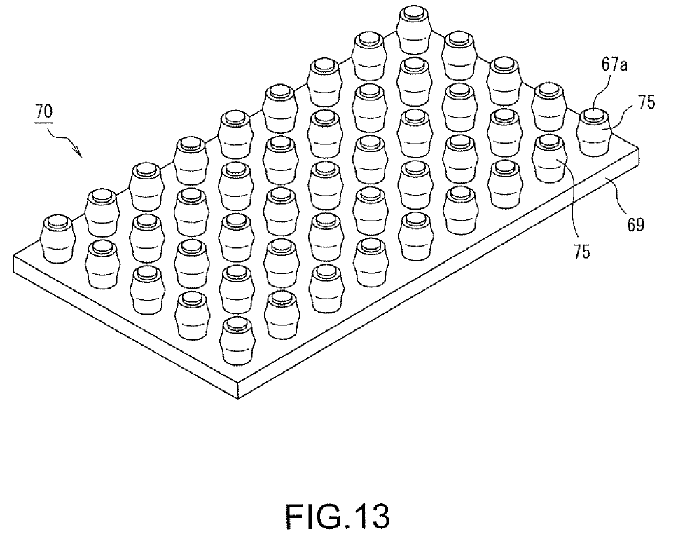

Referring to FIG. 13, the completed substrate 70 has the plurality of the posts 75 which are arranged in more than one line both in the lengthwise direction and the crosswise direction. The posts 75 are adhesively bonded to the supporting substrate 69 with adhesive (not shown in the drawings). A planer shape of the post 75 can be for example a precise circle or other shapes (for example polygons). In this way, the same advantageous effect as that of the substrate 60 described in the second embodiment can be obtained. A positional relation and sizes of the post 75 and the plated layer 67a are for example same as those of the post 37 and the plated layer 43a described above with reference to FIG. 8A and FIG. 8B.

After the substrate 70 is completed, the recognition mark 8 is provided by coloring the upper face (front face) of the post 75 which is placed at a desired position by using for example an inkjet method, a printing method, a dispensing method or a laser marking method. A method for manufacturing a semiconductor device 300 by mounting an IC element on the substrate 70 will be now described.

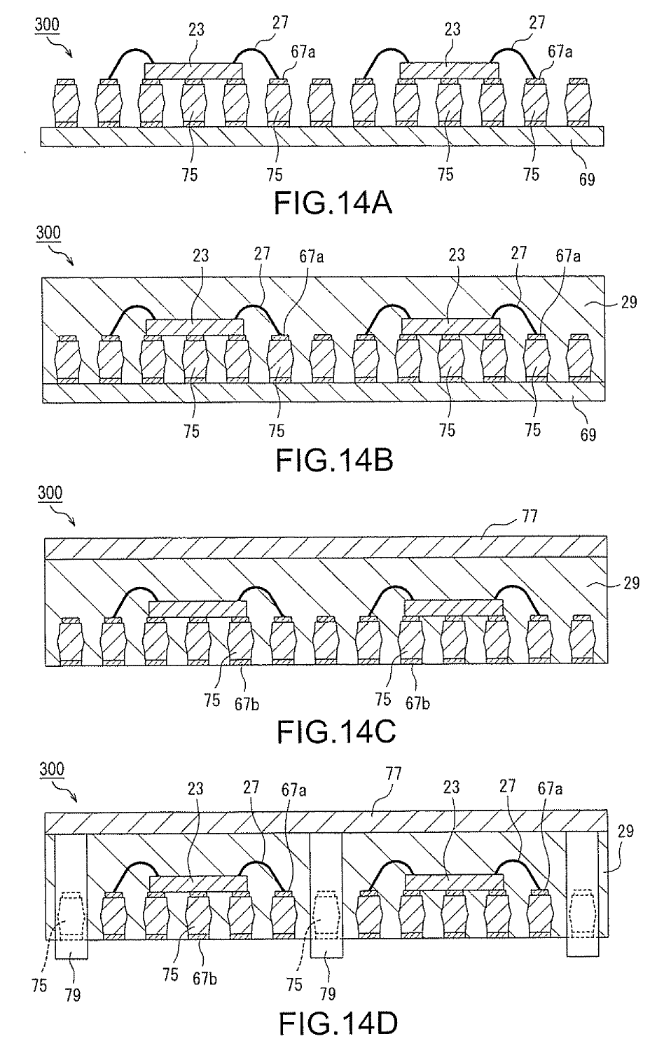

Referring to FIG. 14A is a sectional view showing a method for manufacturing a semiconductor device 300 according a third embodiment of the invention.

Referring to FIG. 14A, unshown adhesive is applied onto the upper face of the post 75 (hereunder referred as a first post) that is in the IC fixing area or onto the lower face of the IC element 23. The IC fixing area is then identified by using an unshown recognition mark, and the IC element 23 is aligned and disposed in the identified IC fixing area. Since the IC fixing area is identified by using the recognition mark as a guide, the IC element 23 can be accurately aligned on the substrate 70, and the IC element 23 can be mounted on the substrate without causing misalignment or with a least displacement (a die attaching step).

The upper face of the post 75 (in other words, the second post) that is located in an area other than the IC fixing area and the pad terminal that is disposed on the front face of the IC element 23 are coupled each other with for example the gold wire 27. Here, the second post 75 which serves as the external terminal is recognized by using an unshown recognition mark as a guide, and one end of the gold wire 27 is coupled to the recognized second post 75 (the wire-bonding step).

Referring to FIG. 14B, the mold resin 29 is supplied onto the upper part of the supporting substrate 69, and the whole upper face side of the supporting substrate 69 including the IC element 23, the gold wire 27 and the post 75 is sealed with the mold resin 29 (the resin sealing step). In this resin sealing step, for example, a metal mold (unshown in the drawings) that can contain the IC element 23 and the plurality of the posts 75 and the like is placed over the supporting substrate 69, then the high temperature (of or example higher than 150° C.) mold resin 29 is injected into the metal mold. The supporting substrate 69 used here is for example a glass substrate, and its coefficient of thermal expansion is relatively small. Therefore the supporting substrate is not stretched in the lengthwise direction or crosswise direction when viewed in plan even if heat as high as 200° C. is applied in the resin sealing step. Consequently, it is possible to retain the distance between two adjacent posts 75 unchanged during the resin sealing step.

The mold resin 29 containing the IC element 23, the gold wire 27 and the post 75 is subsequently removed from the supporting substrate 69. When an ultraviolet curable adhesive is used as the adhesive, adhesion can be weakened by irradiating the adhesive with ultraviolet (UV) rays before actually peeling the resin off from the supporting substrate. Alternatively the mold resin 29 containing the IC element 23 can be removed from the supporting substrate by simply using a mechanical force. Once the mold resin 29 is removed from the supporting substrate 69, the post 75 that is coated with the plated layer 67b is exposed from the lower face (the face peeled off from the supporting substrate 69) of the mold resin 29 as for example illustrated in FIG. 14C. Unshown adhesive remains after the mold resin 29 is removed from the supporting substrate 69 can be left either on the mold resin 29 side or the supporting substrate 69 side.

A product mark (not shown in the drawings) and the like can be inscribed on the upper face (the face where the terminals are not exposed) of the mold resin 29 by using for example ink and laser. Referring to FIG. 14C, an ultraviolet curable tape 77 (or a UV tape) is sequentially provided on the whole upper face of the mold resin 29. Here, the TV tape 77 can be provided on the whole lower face instead of the upper face of the mold resin 29.

Referring to FIG. 14D, the dicing blade 79 is contacted with the face (for example the lower face) of the mold resin 29 where the UV tape 77 is not provided in order to cut the mold resin 29 according to a product profile (a dicing step). In this dicing step, referring to FIG. 14D, the mold resin 29 can be cut at the position where the row or column of the posts 75 exists. Alternatively the mold resin 29 can be cut at the position between the rows or columns of the posts 75 though it is not illustrated in the drawings. Through the dicing step, the semiconductor device 300 is completed. The lower face side of the post 75 which is exposed from the mold resin 29 can remain covered with the plated layer 67b or a solder ball or the like can be provided so as to cover the plated layer 67b.

When the mold resin 29 is cut at the position where the row or column exists, the post 75 that is located at the cutting position (which is shown by the dashed line) is removed. Thereby a contact interface of the post 75 and the mold resin 29 is not exposed in the cut plane. Consequently the semiconductor device has a structure in which water and the like will not enter into the contact interface, in this way it is possible to increase the reliability of the semiconductor device 300. This advantageous effect also applies to the second embodiment.

Examples of the chip size, the number of terminals under the chip (in other words, the number of posts 75), the maximum number of external terminals and the dimension of the package, which can be applied to the semiconductor device 300 according to the third embodiment, are for example listed in Table 1 above.

According to the third embodiment, the rigidity of the plated layer 67a as a whole can be increased and tips of the plated layer 67a will not be broken or come off in the same manner as the first and second embodiments. Therefore it is possible to prevent the migration failure due to the brake or peel off of the plated layer 67a from happening. In addition, chances of burr formation are reduced, which contributes to the stabilization of the planar shapes of the post 75. Therefore in the wire-bonding process, for example, a jointing area in the upper face of the post 75 can be precisely recognized and one end of the gold wire 27 can be appropriately connected to the area. In this way, it is possible to increase the manufacturing efficiency of the semiconductor device 300. Moreover, in the resin sealing step, the “eaves” which can be an obstacle in the sealing step does not exist so that the mold resin can easily fill into a groove between the posts 75. Thereby it is possible to prevent a void space and the like from being generated in the resin package, which increases the reliability of the resin package.

Moreover, according to the third embodiment, the substrate has a specification for mounting various types of elements and can be standardized without increasing constraints on layouts (arrangements) of pad terminals in the same way as the second embodiment. In other words, according to the embodiment, it is possible to provide the substrate which is highly versatile for various types of elements. In this way, the manufacturing costs of the substrate and the semiconductor device 300 equipped with the substrate can be reduced.

What is claimed is:

1. A semiconductor device, comprising:
a first metal post that has a first face;
a second metal post that has a second face;
a first plated layer that is provided on the first face, the first plated layer being discontiguous with an outer edge of the first face;
a second plated layer that is provided on the second face, the second plated layer being discontiguous with an outer edge of the second face;
an integrated circuit element that is fixed on the first face;
a conductor that electrically connects the integrated circuit element with the second metal post; and
a resin that seals the integrated circuit element and the conductor.

2. The semiconductor device according to claim 1, wherein the first metal post has a shape and a size that are same as a shape and a size of the second metal post.

3. The semiconductor device according to claim 1, wherein the second metal post is smaller than the first metal post.

4. A method for manufacturing a semiconductor device, comprising:
providing a substrate that includes a first metal post having a first face, a second metal post having a second face, a first plated layer being provided on the first face the first plated layer being discontiguous with an outer edge of the first face, and a second plated layer being provided on the second face, the second plated layer being discontiguous with an outer edge of the second face;
placing an integrated circuit element on the first face;
connecting the IC element and the second metal post electrically with a conductor; and
sealing the integrated circuit element and the conductor with a resin.
